(19) United States
(12) Patent Application Publication
(10) Pub. No.: US 2024/0321905 A1
(43) Pub. Date: Sep. 26, 2024

(54) DISPLAY SUBSTRATE AND DISPLAY DEVICE

(71) Applicants: HEFEI BOE OPTOELECTRONICS TECHNOLOGY CO., LTD., Hefei, Anhui (CN); BOE TECHNOLOGY GROUP CO., LTD., Beijing (CN)

(72) Inventors: Cheng LI, Beijing (CN); Xiaojie ZHANG, Beijing (CN); Sheng WANG, Beijing (CN)

(73) Assignees: HEFEI BOE OPTOELECTRONICS TECHNOLOGY CO., LTD., Hefei, Anhui (CN); BOE TECHNOLOGY GROUP CO., LTD., Beijing (CN)

(21) Appl. No.: 18/262,395

(22) PCT Filed: Sep. 28, 2022
(86) PCT No.: PCT/CN2022/122027

§ 371 Date: Jul. 21, 2023

(30) Foreign Application Priority Data
Nov. 30, 2021 (CN) 202111441149.X

(51) Int. Cl. H01L 27/12; G02F 1/1362; H01L 27/02

(52) U.S. Cl. CPC H01L 27/1244; G02F 1/136204; G02F 1/136209; G02F 1/136222; G02F 1/136286; H01L 27/0251

(57) ABSTRACT

A display substrate includes a display region and a peripheral region surrounding the display region, the peripheral region includes a bonding region and a profiled region, the display region is between the bonding region and the profiled region. The display substrate further includes a plurality of compensation scanning lines and a plurality of data lines, at least one of the compensation scanning lines includes a portion in the profiled region, and at least one of the data lines includes a portion in the display region and a portion in the profiled region. An electrostatic discharge circuit and a loading compensation structure are arranged in the profiled region, at least part of the electrostatic discharge circuit is located between the display region and the loading compensation structure, and the electrostatic discharge circuit is coupled to the plurality of data lines.

### CROSS-REFERENCE TO RELATED APPLICATIONS

This application claims priority to Chinese Patent Application No. 202111441149.X, filed in China on Nov. 30, 2021, which is hereby incorporated by reference.

### TECHNICAL FIELD

The present disclosure relates to the field of display technologies, in particular to a display substrate and a display device.

### BACKGROUND

Along with the development of display technology, a profiled display product has been widely used. The profiled display product includes a display region and a peripheral region surrounding the display region, a width of the peripheral region determines a width of a frame of the profiled display product. Therefore, in order to provide profiled display product with a narrow frame in a better manner, it is necessary to improve the layout manner of each structure in the peripheral region of the profiled display product.

### SUMMARY

An object of the present disclosure is to provide a display substrate and a display device.

In order to achieve the above object, the present disclosure provides the following technical solutions.

In a first aspect, the present disclosure provides a display substrate, including: a display region and a peripheral region surrounding the display region, the peripheral region including a bonding region and a profiled region, at least part of the display region being located between the bonding region and the profiled region. The display substrate further includes a plurality of compensation scanning lines and a plurality of data lines, at least one of the compensation scanning lines includes a portion located in the profiled region, and at least one of the data lines includes a portion located in the display region and a portion located in the profiled region. An electrostatic discharge circuit and a loading compensation structure are arranged in the profiled region, at least part of the electrostatic discharge circuit is located between the display region and the loading compensation structure. The electrostatic discharge circuit is coupled to the plurality of data lines.

Optionally, the display substrate further includes a common signal line, an orthogonal projection of the common signal line onto a base substrate of the display substrate at least partially overlaps an orthogonal projection of the plurality of compensation scanning lines onto the base substrate, and the common signal line serves as the loading compensation structure.

Optionally, the common signal line is arranged surrounding the display region, the common signal line includes a compensation part and a non-compensation part, the compensation part is located in the profiled region, in a direction perpendicular to an extending direction of the compensation part, a minimum distance from a boundary of the compensation part close to the display region to a boundary of the compensation part away from the display region is greater than a width of the non-compensation part in a direction perpendicular to an extending direction of the non-compensation portion. An orthogonal projection of the compensation part onto the base substrate of the display substrate at least partially overlaps the orthogonal projection of the plurality of compensation scanning lines onto the base substrate, and the compensation part serves as the loading compensation structure.

Optionally, the compensation part is formed in a grid structure.

Optionally, the compensation part includes a first sub-part and a second sub-part, the first sub-part is located between the display region and the second sub-part. The first sub-part includes a hollowed-out region. The profiled region includes a bottom region and a sloped region, along a direction from the sloped region to the bottom region, distances from a boundary of the first sub-part close to the display region to a boundary of the first sub-part away from the display region in a direction perpendicular to an extending direction of the first sub-part gradually decrease, and widths of the second sub-part in a direction perpendicular to an extending direction of the second sub-part gradually increase.

Optionally, the display substrate includes sub-pixels in rows, and the sub-pixels in at least part of the rows includes a plurality of sub-pixels arranged sequentially in a first direction. The compensation scanning line is coupled to each sub-pixel in a corresponding row. The plurality of compensation scanning lines includes a first compensation scanning line to an Nth compensation scanning line, the quantity of sub-pixels in a row corresponding to an Xth compensation scanning line is less than the quantity of sub-pixels in a row corresponding to an (X+1)th compensation scanning line, where 1≤ X≤N−1. An overlapping area between an orthogonal projection of the Xth compensation scanning line onto the base substrate and the orthogonal projection of the compensation part onto the base substrate is greater than an overlapping area between an orthogonal projection of the (X+1)th compensation scanning line onto the base substrate and the orthogonal projection of the compensation part onto the base substrate.

Optionally, the display region includes a first display region and two second display regions, the first display region is located on a same side of the two second display regions, and the profiled region is located between the two display regions. The sub-pixels in rows includes first sub-pixels in rows and second sub-pixels in rows, the first sub-pixels in rows are located in the first display region, and among the second sub-pixels in rows, one part of the second sub-pixels in each row is located in one of the second display regions, and the other part of the second sub-pixels in each row is located in the other one of the second display regions. At least one of the plurality of compensation scanning lines corresponds to the second sub-pixels in one row, at least one of the compensation scanning lines includes a first line segment, a second line segment and a third line segment sequentially coupled, the first line segment and the third line segment each include at least a portion extending in the first direction, and the second line segment extends along a boundary of the profiled region. An orthogonal projection of the first line segment onto the base substrate at least partially overlaps the orthogonal projection of the compensation part onto the base substrate, an orthogonal projection of the second line segment onto the base substrate at least partially overlaps the orthogonal projection of the compensation part onto the base substrate, and an orthogonal projection of the third line segment onto the base substrate at least partially overlaps the orthogonal projection of the compensation part onto the base substrate.

Optionally, the display substrate further includes a plurality of non-compensation scanning lines, at least part of the non-compensation scanning lines are located in the first display region, at least one of the plurality of non-compensation scanning lines corresponds to, and is coupled to, the first sub-pixels in one row. The compensation scanning lines and the non-compensation scanning lines are arranged at a same layer, and the common signal line and the data lines are arranged at a same layer.

Optionally, the non-compensation part includes a first non-compensation part and a second non-compensation part, the display region is located between the first non-compensation part and the second non-compensation part, a first end of the first non-compensation part is coupled to a first end of the compensation part, a second end of the first non-compensation part is located in the bonding region, a first end of the second non-compensation part is coupled to a second end of the compensation part, and a second end of the second non-compensation part is located in the bonding region.

Optionally, the display substrate further includes a shielding line in the peripheral region, the shielding line is arranged surrounding the display region, and the common signal line is located between the display region and the shielding line.

Optionally, the electrostatic discharge circuit includes a plurality of electrostatic discharge sub-circuits corresponding to the plurality of data lines respectively. At least one of the electrostatic discharge sub-circuits includes a first transistor and a second transistor, a gate electrode of the first transistor is coupled to an input electrode of the first transistor, the input electrode of the first transistor is coupled to an input electrode of the second transistor, an output electrode of the first transistor is coupled to an output electrode of the second transistor, and a gate electrode of the second transistor is coupled to the output electrode of the second transistor; the input electrode of the first transistor is coupled to a corresponding data line.

Optionally, the input electrode of the first transistor and the input electrode of the second transistor are formed as an integral structure with a corresponding data line.

Optionally, the plurality of electrostatic discharge sub-circuits is divided into a plurality of electrostatic discharge sub-circuit groups arranged sequentially in the profiled region, at least one of the electrostatic discharge sub-circuit groups includes at least two electrostatic discharge sub-circuits, and gate electrodes of second transistors in at least one of the electrostatic discharge sub-circuit groups are formed as one piece.

Optionally, the plurality of compensation scanning lines is divided into a plurality of compensation scanning line groups, at least one of the compensation scanning line groups includes at least two adjacent compensation scanning lines, and at least part of the electrostatic discharge sub-circuit groups are located between adjacent compensation scanning line groups.

Based on the technical solution of the above-mentioned display substrate, in a second aspect, the present disclosure provides a display panel including the above-mentioned display substrate. The display panel further includes an opposing substrate arranged opposite to the display substrate, and the opposing substrate includes: a black matrix layer, where the black matrix layer includes a display region pattern and a non-display region pattern, an orthogonal projection of the display region pattern onto the display substrate is located in the display region of the display substrate, and an orthogonal projection of the non-display region pattern onto the display substrate is located in the peripheral region of the display substrate; a black matrix hollowed-out region is provided between the display region pattern and the non-display region pattern.

Optionally, an orthogonal projection of the electrostatic discharge circuit of the display substrate onto the base substrate of the display substrate is located between an orthogonal projection of the loading compensation structure of the display substrate onto the base substrate and an orthogonal projection of the black matrix hollowed-out region onto the base substrate.

Optionally, the opposing substrate further includes a support layer, and at least part of the support layer is located in the black matrix hollowed-out region.

Optionally, the support layer includes a blue color filter pattern including a portion in the black matrix hollowed-out region and a portion at a periphery of the black matrix hollowed-out region.

Optionally, the display panel further includes a sealant between the display substrate and the opposing substrate, an orthogonal projection of the sealant onto the display substrate is located in the peripheral region of the display substrate, and the orthogonal projection of the sealant onto the base substrate at least partially overlaps an orthogonal projection of a hollowed-out region in the common signal line of the display substrate onto the base substrate.

Based on the technical solution of the display panel described above, in a third aspect, the present disclosure provides a display device including the above-mentioned display panel.

### BRIEF DESCRIPTION OF THE DRAWINGS

The following drawings are provided to facilitate the understanding of the present disclosure, and constitute a portion of the present disclosure. These drawings and the following embodiments are for illustrative purposes only, but shall not be construed as limiting the present disclosure. In these drawings,

FIG. 1 is a first schematic view showing an overall structure of a display substrate according to the embodiments of the present disclosure;

FIG. 2 is a schematic view showing a structure of a display panel close to a profiled region according to the embodiments of the present disclosure;

FIG. 3 is an enlarged view of a portion X1 in FIG. 2;

FIG. 4 is a schematic view of FIG. 3 with a common signal line removed;

FIG. 5 is a schematic view showing a case where of the common signal line overlaps a compensation scanning line according to the embodiments of the present disclosure;

FIG. 6 is a schematic view showing two electrostatic discharge sub-circuits according to the embodiments of the present disclosure;

FIG. 7 is a schematic diagram of two electrostatic discharge sub-circuits coupled to respective data lines according to the embodiments of the present disclosure;

FIG. 8 is a schematic diagram of an electrostatic discharge sub-circuit group coupled to a corresponding data line according to the embodiments of the present disclosure;

FIG. 9 is a schematic view showing part of a black matrix layer according to the embodiments of the present disclosure;

FIG. 10 is a sectional view of a portion X3 in FIG. 3 along a direction perpendicular to a boundary of the profiled region;

FIG. 11 is a schematic diagram of a loading difference between compensation and non-compensation scanning lines according to the embodiments of the present disclosure;

FIG. 12 is a second schematic view showing the overall structure of the display substrate according to the embodiments of the present disclosure;

FIG. 13 is a schematic view showing a case where a plurality of electrostatic discharge sub-circuits is coupled to data lines according to the embodiments of the present disclosure;

FIG. 14 is a schematic view showing the layout of a gate metal layer, an active layer and a source/drain metal layer in FIG. 13;

FIG. 15 is a schematic view showing the layout of the source/drain metal layer in FIG. 13;

FIG. 16 is a schematic view showing the layout of an indium tin oxide layer in FIG. 13.

### DETAILED DESCRIPTION

In order to further explain the display substrate and the display device provided by the embodiments of the present disclosure, a detailed description will be given below with reference to the accompanying drawings.

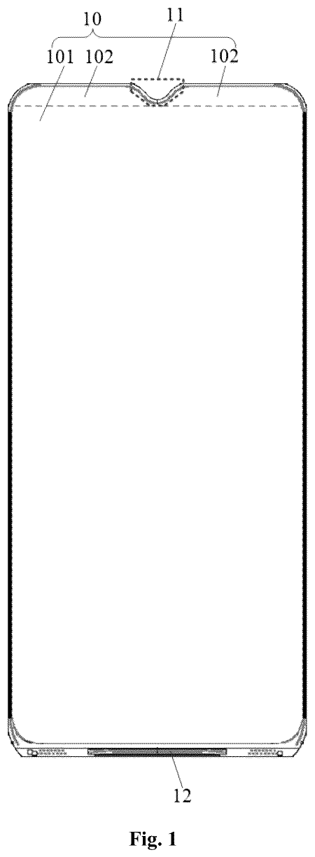

With reference to FIGS. 1-4, the present disclosure provides in some embodiments a display substrate, including: a display region 10 and a peripheral region surrounding the display region 10, the peripheral region including a bonding region 12 and a profiled region 11, at least part of the display region 10 being located between the bonding region 12 and the profiled region 11. It should be appreciated that the profiled region 11 refers to a non-linear region of the display panel, for example, including an arc-shaped region, a zigzag-shaped region, and in the profiled region 11, a length between two selected points is greater than a distance of a straight line between the two selected points.

The display substrate further includes a plurality of compensation scanning lines 20 and a plurality of data lines 30, at least one of the compensation scanning lines 20 includes a portion located in the profiled region 11, and at least one of the data lines 30 includes a portion located in the display region 10 and a portion located in the profiled region 11.

An electrostatic discharge circuit and a loading compensation structure are arranged in the profiled region 11, at least part of the electrostatic discharge circuit is located between the display region 10 and the loading compensation structure.

The electrostatic discharge circuit is coupled to the plurality of data lines 30, and the loading compensation structure is used for compensating the loading of the compensation scanning line 20.

Illustratively, the compensation scanning line 20 further includes a portion in the display region 10. It should be appreciated that all scanning lines in the display substrate include two types of scanning lines which are the compensation scanning lines and non-compensation scanning lines, respectively. The non-compensation scanning line includes a portion in a first display region, and is connected to a first sub-pixel in the first display region. The compensation scanning line is connected to a second sub-pixel in a second display region, and includes the portion in the display region 10 and the portion in the profiled region 11.

Illustratively, the display substrate is applied in a liquid crystal display panel, the display substrate includes an array substrate. The display substrate includes the display region 10 and the peripheral region. The peripheral region includes the bonding region 12 and the profiled region 11, the bonding region 12 is located at a lower frame of the display substrate, and the profiled region 11 is located at an upper frame of the display substrate. Optionally, a driving chip is bonded in the bonding region 12, i.e., a COG (chip on glass) scheme, or, a flexible circuit board is bonded in the bonding region 12, and the driving chip is bonded to the flexible circuit board, i.e., a COF (chip on film) scheme, which will not be particularly defined herein.

Illustratively, the display substrate may be further applied in an organic light emitting diode display panel.

Illustratively, in the display panel to which the display substrate is applied, a transistor may include an a-Si transistor, a low temperature polysilicon (LTPS) transistor, etc.

Illustratively, the compensation scanning line 20 includes at least a portion extending in a first direction and the data line 30 includes at least a portion extending in a second direction crossing the first direction. Illustratively, the first direction includes a lateral direction and the second direction includes a longitudinal direction.

Illustratively, the portion of the compensation scanning line 20 in the display region 10 is coupled to a corresponding sub-pixel. The portion of the data line 30 in the display region 10 is coupled to sub-pixels in a corresponding column, and the portion of the data line 30 in the profiled region 11 is coupled to the electrostatic discharge circuit.

Illustratively, both the electrostatic discharge circuit and the loading compensation structure are located in the profiled region 11, at least part of an orthogonal projection of the electrostatic discharge circuit onto the base substrate of the display substrate is between an orthogonal projection of the loading compensation structure onto the base substrate and the display region 10.

Illustratively, the electrostatic discharge circuit is coupled to the plurality of data lines 30, so as to discharge electrostatic charges on the plurality of data lines 30, thereby to ensure the stable operation of the display substrate.

A case where the profiled region 11 is of a V-shape, a U-shape or a circular-arc shape is taken as an example. The display substrate includes a first display region 101 and two second display regions 102, the first display region 101 is located on the same side of the two second display regions 102, and the profiled region 11 is located between the two display regions.

The display substrate includes sub-pixels in rows including first sub-pixels in rows and second sub-pixels in rows, the first sub-pixels in rows is located in the first display region 101, and among the second sub-pixels in rows, one part of the second sub-pixels in each row is located in one of the second display regions 102, and the other part of the second sub-pixels in each row is located in the other one of the second display regions 102. The quantity of first sub-pixels in each row is greater than the quantity of second sub-pixels in each row.

The display substrate includes the plurality of compensation scanning lines 20 and a plurality of non-compensation scanning lines, at least one of the plurality of non-compensation scanning lines corresponds to, and is coupled to, the first sub-pixels in one row. At least one of the plurality of compensation scanning lines 20 corresponds to, and is coupled to, the second sub-pixels in one row. It should be appreciated that each first sub-pixel and each second sub-pixel have a same structure, but have different names just because they are in different display regions.

Since the quantity of second sub-pixels coupled to the compensation scanning line 20 is less than the quantity of first sub-pixels coupled to the non-compensation scanning line, the loading of the compensation scanning line 20 is less than the loading of the non-compensation scanning line, and in order to ensure that the loading of the compensation scanning line 20 and the non-compensation scanning line are uniform, loading compensation is required for the compensation scanning line 20. A compensation value of the loading compensation for the compensation scanning line 20 is determined according to a difference between the quantity of second sub-pixels coupled to the scanning line and the quantity of first sub-pixels in one row, and the difference is related to a shape of the profiled region 11.

Illustratively, the loading compensation structure is configured to compensate for the loading of the compensation scanning line 20, so that the loading of the compensation scanning line 20 is close to or equal to the loading of the non-compensation scanning line.

According to the above-mentioned specific structure of the display substrate in the embodiments of the present disclosure, both the electrostatic discharge circuit and the loading compensation structure are arranged in the profiled region 11, and the electrostatic discharge circuit is arranged between the display region 10 and the loading compensation structure. The electrostatic discharge circuit is arranged close to the display region, and there is no other structure between the electrostatic discharge circuit and the display region 10, it is able for the electrostatic discharge circuit to be immediately adjacent to the data line 30 coupled thereto, thereby not only to reduce the difficulty in coupling between the electrostatic discharge circuit and the data line 30, but also to reduce a distance between the electrostatic discharge circuit and the data line 30. As a result, it is able to reduce the layout space occupied by the electrostatic discharge circuit and the data line 30 coupled thereto as a whole, thereby to provide the display substrate at a side where the profiled region 11 is located with a narrow frame.

Furthermore, in the display substrate according to the embodiments of the present disclosure, the electrostatic discharge circuit arranged at the lower frame of the display substrate in the related art is moved to the profiled region 11, thereby to effectively reduce a width of the lower frame of the display substrate. In addition, when the electrostatic discharge circuit is moved to the profiled region 11, a part of the structure in the profiled region 11 may be removed, and a space originally used for arranging the part of the structure is used for arranging the electrostatic discharge circuit, so that even the electrostatic discharge circuit is moved to the profiled region 11, a width of the frame of the display substrate where the profiled region 11 is located is not increased.

In more detail, in the related art, when the electrostatic discharge circuit is arranged at the lower frame, a width of the lower border occupied by the electrostatic discharge circuit is between 70 μm and 100 μm, with end points inclusive. In the display substrate of the embodiments of the present disclosure, a partial layout space is vacated through removing a part of the structure in the profiled region 11 or changing a part of the structure in the profiled region 11, the electrostatic discharge circuit is moved from the lower border to the vacated layout space. In this regard, it is able for the width of the lower frame of the display substrate to be reduced by at least 70 μm without increasing the width of the frame at the profiled region 11.

In addition, the loading compensation structure compensates for the loading of the compensation scanning line 20, it is able to reduce the loading difference between the compensation scanning line 20 and the non-compensation scanning line, thereby to ensure the loading uniformity of the compensation scanning line 20 and the non-compensation scanning line in a better manner, and effectively improve the display quality of the display substrate.

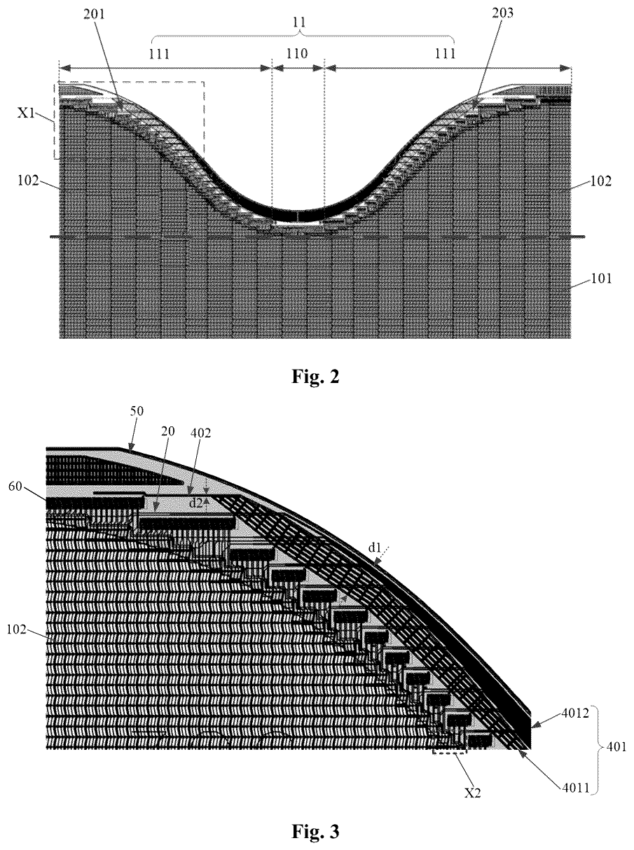

As shown in FIGS. 2-4 and 10, in some embodiments of the present disclosure, the display substrate further includes a common signal line (including a compensation part 401 and a non-compensation part 402), an orthogonal projection of the common signal line onto the base substrate of the display substrate overlaps an orthogonal projection of the plurality of compensation scanning lines 20 onto the base substrate, the common signal line serves as the loading compensation structure.

Illustratively, the common signal line is configured to transmit a common signal.

By way of example, the display substrate further includes a common electrode 81 located in the display region 10, the common signal line and the common electrode 81 are structurally independent from each other, but electrically connected to each other, namely, the common signal line provides a common signal for the common electrode, so that a voltage difference for driving the liquid crystal to rotate is formed between the common electrode and a pixel electrode of the display region, thereby to realize the display function of the display panel.

Illustratively, the common signal line is arranged at a different layer from the compensation scanning line 20, and an insulating layer is disposed between the common signal line and the compensation scanning line 20. The orthogonal projection of the common signal line onto the base substrate 82 at least partially overlaps the orthogonal projection of the compensation scanning line 20 onto the base substrate 82, and thus a compensating capacitance between the common signal line and the compensation scanning line 20 is formed, thereby to realize the capacitance loading compensation for the compensation scanning line 20. Furthermore, the compensation scanning line 20 extends along the profiled region 11, such that the compensation scanning line 20 has a longer length, thereby to realize the resistance loading compensation for the compensation scanning line 20. Thus, in the display substrate of the above-mentioned embodiments, it is able to realize the resistance-capacitance loading compensation for the compensation scanning line 20.

In more detail, the quantity of sub-pixels connected to the non-compensation scanning line in the first display region 101 along an extending direction of the non-compensation scanning line is larger than the quantity of sub-pixels connected to the compensation scanning line in the second display region 102. With regard to one sub-pixel, it is in a region defined by the scanning line crossing the data line, one sub-pixel includes a common electrode and a pixel electrode corresponding thereto forming a capacitance for driving the liquid crystal to rotate. Therefore, capacitances corresponding to the first display region 101 and the second display region 102 for driving the liquid crystal to rotate are not consistent, i.e., the loadings of the first display region 101 and the second display region 102 are not consistent, and a non-uniform display image occurs subsequently. In the present disclosure, through providing a compensation structure in the profiled region 11, it is able to provide a uniform display image.

In the display substrate of the above-mentioned embodiments, the common signal line transmits a common signal when the display substrate is in an operating state, and it is able for the common signal line, on the one hand, to shield stray signals generated in the peripheral region during the operation of the display substrate, on the other hand, to form a compensation capacitance with the compensation scanning line 20, i.e., to serve as the loading compensation structure, to realize the loading compensation for the compensation scanning line 20. Therefore, in the display substrate of the above-mentioned embodiments, when the common signal line serves as the loading compensation structure, it is able to simplify the complexity in the layout of the structure in the profiled region 11, and reduce the width of the frame of the display substrate at the profiled region 11.

In more detail, FIG. 11 shows a curve L4 of a loading difference between the compensation scanning line 20 and the non-compensation scanning line in the embodiment of the present disclosure is illustrated, and a curve L3 of a loading difference between two adjacent scanning lines (which may be the compensation scanning line 20 and the non-compensation scanning line adjacent to each other, or adjacent compensation scanning lines 20) in the embodiments of the present disclosure. It should be appreciated that the abscissa in FIG. 11 represents the quantity of rows of the second sub-pixels. A positive number on the ordinate in FIG. 11 represents that the loading of the compensation scanning line 20 after compensation is greater than the loading of the non-compensation scanning line. A negative number on the ordinate in FIG. 11 represents that the loading of the compensation scanning line 20 after compensation is less than the loading of the non-compensation scanning line.

As shown in FIG. 11, in the embodiments of the present disclosure, it is able for a maximum loading difference between the compensation scanning line 20 and the non-compensation scanning line to be controlled within 7%, and the loading difference between two adjacent scanning lines to be controlled within ±1%.

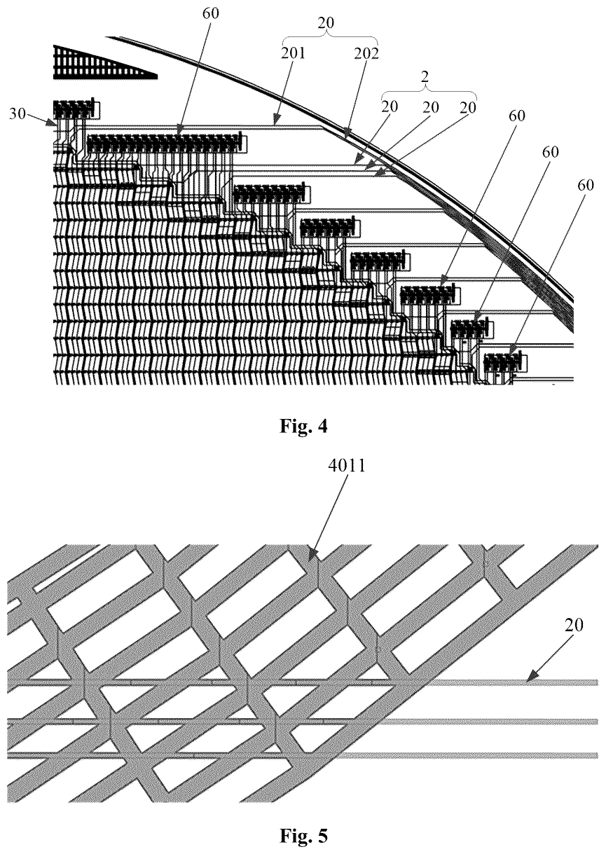

As shown in FIGS. 2 to 5, in some embodiments of the present disclosure, the common signal line is arranged surrounding the display region 10, the common signal line includes a compensation part 401 and a non-compensation part 402, the compensation part 401 is located in the profiled region 11, and in a direction perpendicular to an extending direction of the compensation part 401, a minimum distance d1 from a boundary of the compensation part 401 close to the display region 10 to a boundary of the compensation part 401 away from the display region 10 is greater than a width d2 of the non-compensation part 402 in a direction perpendicular to an extending direction of the non-compensation portion.

An orthogonal projection of the compensation part 401 onto the base substrate 82 of the display substrate at least partially overlaps the orthogonal projection of the plurality of compensation scanning lines 20 onto the base substrate 82, and the compensation part 401 serves as the loading compensation structure.

Illustratively, the compensation part 401 and the non-compensation part 402 are formed as one piece and at a same layer.

Illustratively, the compensation part 401 is located in the profiled region 11, and the non-compensation part 402 includes a portion located in the profiled region 11 and a portion located in a region of the peripheral region other than the profiled region 11.

Illustratively, the compensation part 401 serves as the loading compensation structure, and when controlling a size of the overlapping area between the orthogonal projection of the compensation part 401 onto the base substrate 82 and the orthogonal projection of the compensation scanning line 20 onto the base substrate 82, it is able to control the degree of compensation for the loading of the compensation scanning line 20.

In the direction perpendicular to the extending direction of the compensation part 401, the minimum distance from the boundary of the compensation part 401 close to the display region 10 to the boundary of the compensation part 401 away from the display region 10 is greater than the width of the non-compensation part 402 in the direction perpendicular to the extending direction of the non-compensation portion, it is able for the compensation part 401 to compensate for the loading of the compensation scanning line 20 in a better manner, and further for the non-compensation part 402 to reduce the frame width occupied by itself as much as possible while ensuring the shielding function, thereby to provide the display substrate with a narrow frame.

In some embodiments of the present disclosure, the compensation part 401 is formed in a grid structure.

Illustratively, when the display substrate and the opposing substrate are oppositely arranged to form a cell of the display panel, a sealant is formed between the display substrate and the opposing substrate, and cured by irradiating with ultraviolet light, so that the frame of the display panel is fastened into the frame of the opposing substrate by using the sealant.

Illustratively, an orthogonal projection of the sealant onto the base substrate 82 at least partially overlaps the orthogonal projection of the compensation part 401 onto the base substrate 82.

The compensation part 401 is formed in the grid structure, so that when curing the sealant, it is able for the ultraviolet light to pass through the compensation part 401 and irradiate the sealant in a better manner, thereby improving the curing effect of the sealant in a better manner.

As shown in FIGS. 2-5, in some embodiments of the present disclosure, the compensation part 401 includes a first sub-part 4011 and a second sub-part 4012, the first sub-part 4011 is located between the display region 10 and the second sub-part 4012, and the first sub-part 4011 includes a hollowed-out region.

The profiled region 11 includes a bottom region 110 and a sloped region 111, along a direction from the sloped region 111 to the bottom region 110, distances from a boundary of the first sub-part 4011 close to the display region 10 to a boundary of the first sub-part 4011 away from the display region 10 in a direction perpendicular to an extending direction of the first sub-part 4011 gradually decrease, and widths of the second sub-part 4012 in a direction perpendicular to an extending direction of the second sub-part gradually increase.

Illustratively, the first sub-part 4011 and the second sub-part 4012 are formed as one piece.

Illustratively, the first sub-part 4011 includes the hollowed-out region and the second sub-part 4012 does not include a hollowed-out region.

Illustratively, at least part of the first sub-part 4011 is located between the display region 10 and the second sub-part 4012.

Illustratively, the bottom region 110 is closer to the first display region 101 relative to the sloped region 111.

In the direction from the sloped region 111 to the bottom region 110, the distances from the boundary of the first sub-part 4011 close to the display region 10 to the boundary of the first sub-part 4011 away from the display region 10 in the direction perpendicular to the extending direction of the first sub-part 4011 gradually decrease, and the widths of the second sub-part 4012 in the direction perpendicular to its own extending direction gradually increase, so it is able not only to ensure the curing effect of the sealant, but also to facilitate the loading compensation of the compensation scanning line 20.

In more detail, the closer the compensation scanning line 20 to the first display region 101, the smaller the maximum compensation capacitance formed between the compensation scanning line 20 and the compensation part 401. On the basis of the above-mentioned scheme, it is able to effectively improve the maximum capacitance compensation value for the compensation scanning line 20 close to the first display region 101, thereby facilitating the loading uniformity of the scanning lines in the display substrate.

In some embodiments of the present disclosure, the display substrate includes sub-pixels in rows, and the sub-pixels in at least part of the rows include a plurality of sub-pixels arranged sequentially in a first direction. The compensation scanning line 20 is coupled to each sub-pixel in a corresponding row.

The plurality of compensation scanning lines 20 includes a first compensation scanning line to an Nth compensation scanning line, the quantity of sub-pixels in a row corresponding to the Xth compensation scanning line is less than the quantity of sub-pixels in a row corresponding to the (X+1)th compensation scanning line, where 1≤X≤N−1.

An overlapping area between an orthogonal projection of the Xth compensation scanning line onto the base substrate 82 and the orthogonal projection of the compensation part 401 onto the base substrate 82 is greater than an overlapping area between an orthogonal projection of the (X+1)th compensation scanning line onto the base substrate 82 and the orthogonal projection of the compensation part 401 on the base substrate 82.

Illustratively, the first compensation scanning line to the Nth compensation scanning line are sequentially arranged in a direction close to the first display region 101, where N is a positive integer.

By way of example, the quantity of sub-pixels in a row coupled to the corresponding Xth compensation scanning line is less than the quantity of sub-pixels in a row coupled to the corresponding (X+1)th compensation scanning line, a length of a portion of the Xth compensation scanning line in the profiled region 11 is greater than a length of a portion of the (X+1)th compensation scanning line in the profiled region 11, so that the overlapping area between the orthogonal projection of the Xth compensation scanning line onto the base substrate 82 and the orthogonal projection of the compensation part 401 onto the base substrate 82 is greater than the overlapping area between the orthogonal projection of the (X+1)th compensation scanning line onto the base substrate 82 and the orthogonal projection of the compensated portion 401 onto the base substrate 82.

Since the quantity of sub-pixels in the row corresponding to the Xth compensation scanning line is less than the quantity of sub-pixels in the row corresponding to the (X+1)th compensation scanning line, the loading of the Xth compensation scanning line is less than the loading of the (X+1)th compensation scanning line. As a result, when the overlapping area between the orthogonal projection of the Xth compensation scanning line onto the base substrate 82 and the orthogonal projection of the compensation part 401 onto the base substrate 82 is greater than the overlapping area between the orthogonal projection of the (X+1)th compensation scanning line onto the base substrate 82 and the orthogonal projection of the compensation part 401 onto the base substrate 82, the resistance-capacitance loading compensated for the Xth compensation scanning line is greater than the resistance-capacitance loading compensated for the (X+1)th compensation scanning line, thereby adequately ensuring the loading uniformity of the compensation scanning line.

As shown in FIGS. 1 to 5, in some embodiments of the present disclosure, the display region 10 includes a first display region 101 and two second display regions 102, the first display region 101 is located on a same side of the two second display regions 102, and the profiled region 11 is located between the two display regions.

The sub-pixels in rows include first sub-pixels in rows and second sub-pixels in rows, the first sub-pixels in rows are located in the first display region 101, among the second sub-pixels in rows, one part of the second sub-pixels in each row is located in one of the second display regions 102, and the other part of the second sub-pixels in each row is located in the other one of the second display regions 102.

At least one of the plurality of compensation scanning lines 20 corresponds to the second sub-pixels in one row, at least one of the compensation scanning lines 20 includes a first line segment 201, a second line segment 202 and a third line segment 203 sequentially coupled, the first line segment 201 and the third line segment 203 each include at least a portion extending in the first direction, and the second line segment 202 extends along a boundary of the profiled region 11.

An orthogonal projection of the first line segment 201 onto the base substrate 82 at least partially overlaps the orthogonal projection of the compensation part 401 onto the base substrate 82, an orthogonal projection of the second line segment 202 onto the base substrate 82 at least partially overlaps the orthogonal projection of the compensation part 401 onto the base substrate 82, and an orthogonal projection of the third line segment onto the base substrate 82 at least partially overlaps the orthogonal projection of the compensation part 401 onto the base substrate 82.

Illustratively, the first line segment 201, the second line segment 202 and the third line segment are formed as one piece, and at a same layer.

Illustratively, an extension shape of the second line segment 202 is substantially the same as the boundary of the profiled region 11.

Illustratively, the first line segment 201 is coupled to each second sub-pixel in a corresponding row in one of the second display regions 102 (e.g., a left illustration in FIG. 2). The third line segment is coupled to each second sub-pixel in a corresponding row in the other one of the second display regions 102 (e.g., a right illustration in FIG. 2) are coupled. Illustratively, the first line segment 201, the second line segment 202 and the third line segment 203 belonging to a same compensation scanning line 20 correspond to the second sub-pixels in a same row.

On the basis of the above scheme, it is able to realize the loading compensation for the compensation scanning line 20 in a better manner.

In some embodiments of the present disclosure, the display substrate further includes a plurality of non-compensation scanning lines, at least part of the non-compensation scanning lines are located in the first display region 101, at least one of the plurality of non-compensation scanning lines corresponds to, and is coupled to, the first sub-pixels in one row.

The compensation scanning lines 20 are arranged at a same layer as the non-compensation scanning lines, and the common signal line is arranged at a same layer as the data lines 30.

Illustratively, the non-compensation scanning line includes at least a portion extending in the first direction.

Illustratively, the compensation scanning lines 20 and the non-compensation scanning lines are arranged at the same layer and made of a same material, and the common signal line and the data lines 30 are arranged at the same layer and made of a same material.

Illustratively, the compensation scanning lines 20 and the non-compensation scanning lines are formed by using a first gate metal layer. The common signal line and the data lines 30 are formed by a first source/drain metal layer.

On the basis of the above scheme, it is able to enable the compensation scanning lines 20 and the non-compensation scanning lines to be formed in a same patterning process, and the common signal line and the data lines 30 to be formed in a same patterning process, so as to simplify the manufacturing process procedure of the display substrate and reduce the manufacturing cost of the display substrate.

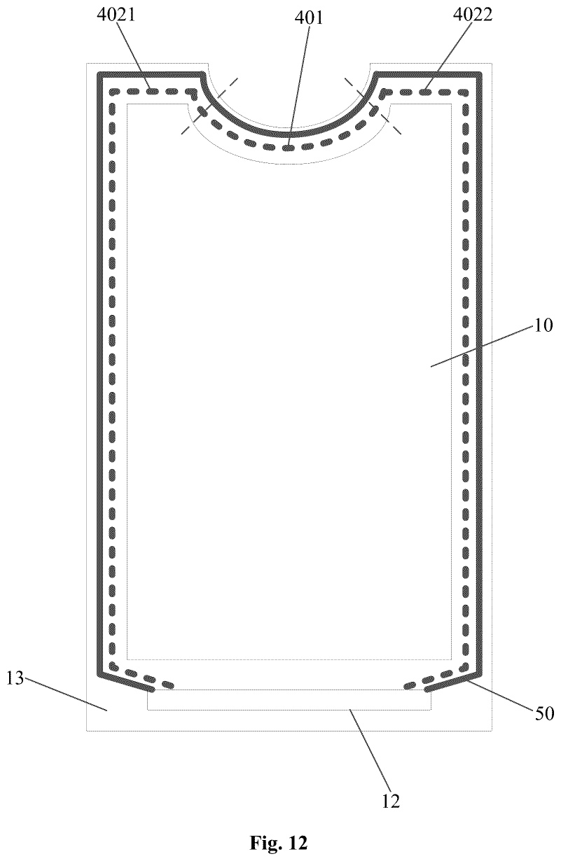

As shown in FIG. 12, in some embodiments of the present disclosure, the non-compensation part 402 includes a first non-compensation part 4021 and a second non-compensation part 4022, the display region 10 is located between the first non-compensation part 4021 and the second non-compensation part 4022, a first end of the first non-compensation part 4021 is coupled to a first end of the compensated portion 401, a second end of the first non-compensation part 4021 is located in the bonding region 12, a first end of the second non-compensation part 4022 is coupled to a second end of the compensated portion 401, and a second end of the second non-compensation part 4022 is located in the bonding region 12.

It should be appreciated that FIG. 12 further shows the peripheral region 13.

Illustratively, the first non-compensation part 4021, the compensation part 401 and the second non-compensation part 4022 are sequentially coupled.

Illustratively, a driving chip is bonded in the bonding region 12, and the second end of the first non-compensation part 4021 and the second end of the second non-compensation part 4022 are coupled to the driving chip.

On the basis of the above scheme, the first non-compensation part, the compensated part 401 and the second non-compensation part are arranged surrounding the display region 10, so, when the display substrate is in the operating state, the common signal line composed of the first non-compensation part, the compensated part 401 and the second non-compensation part is applied with a same common signal as the common electrode 81 in the display substrate, thereby to improve the stability of the operation of the display substrate.

As shown in FIG. 3, in some embodiments of the present disclosure, the display substrate further includes a shielding line 50 in the peripheral region, the shielding line 50 is arranged surrounding the display region 10, and the common signal line is located between the display region 10 and the shielding line 50.

Illustratively, both ends of the shielding line 50 are coupled to the driving chip, and the driving chip provides a GND signal to the shielding line 50.

When the display substrate includes the shielding line 50, it is able for the shielding lines 50 to shield crosstalk signals at the periphery of the display substrate.

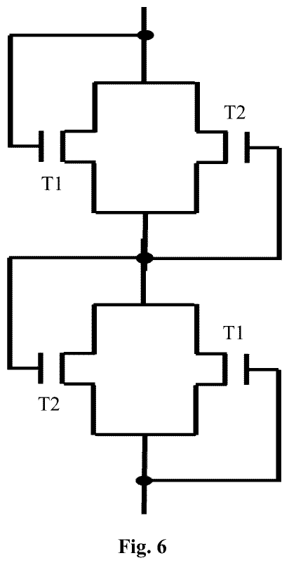

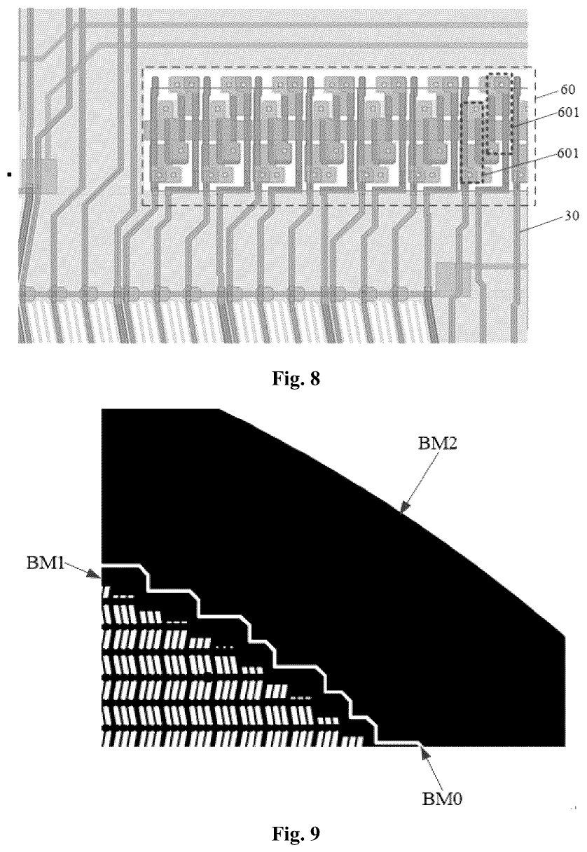

As shown in FIGS. 6 to 8, in some embodiments of the present disclosure, the electrostatic discharge circuit includes a plurality of electrostatic discharge sub-circuits 601 corresponding to the plurality of data lines 30 respectively.

At least one of the electrostatic discharge sub-circuits 601 includes a first transistor T1 and a second transistor T2, a gate electrode of the first transistor T1 is coupled to an input electrode of the first transistor T1, the input electrode of the first transistor T1 is coupled to an input electrode of the second transistor T2, an output electrode of the first transistor T1 is coupled to an output electrode of the second transistor T2, and a gate electrode of the second transistor T2 is coupled to an output electrode of the second transistor T2. The input electrode of the first transistor T1 is coupled to a corresponding data line 30, and the output electrode of the first transistor T1 is coupled to the common signal line.

Illustratively, the electrostatic discharge sub-circuit 601 is capable of discharging a static charge on the correspondingly coupled data line 30 through the first transistor T1 and the second transistor T2 to the common signal line.

In the display substrate of the above-mentioned embodiments, through the electrostatic discharge circuit, the static charge on the data line 30 is discharged to the common signal line, thereby facilitating the stability of the operation of the display substrate.

As shown in FIGS. 6 to 8, in some embodiments of the present disclosure, the input electrode of the first transistor T1, the input electrode of the second transistor T2, and the corresponding data line 30 are formed as one piece.

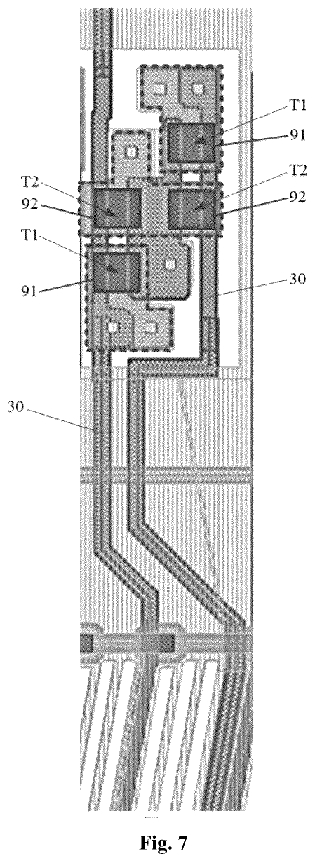

It should be appreciated that, in FIG. 7, a dashed box having an inverted T shape denotes the gate electrodes of two second transistors T2. Dashed boxes above and below the dashed box having the inverted T shape in FIG. 7 denote the gate electrode of the first transistor T1. A first active layer 91 of the first transistor T1 and a second active layer 92 of the second transistor T2 are illustrated in FIG. 7.

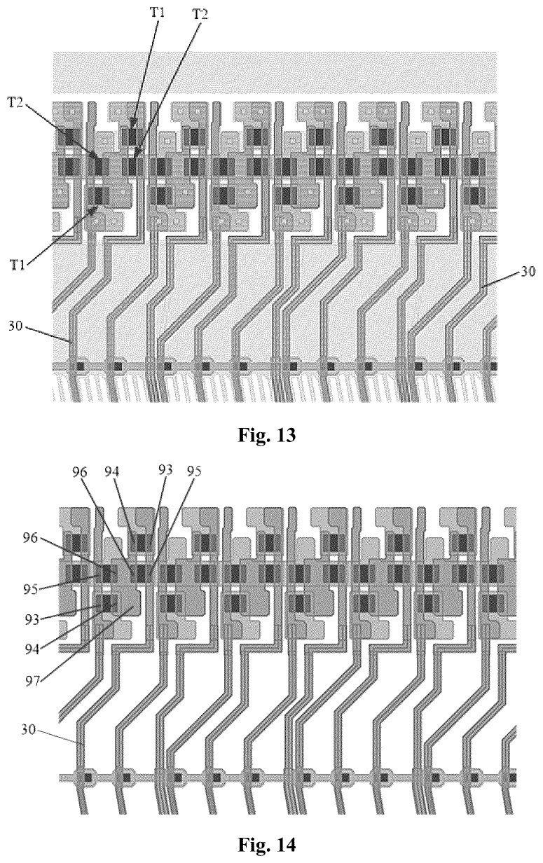

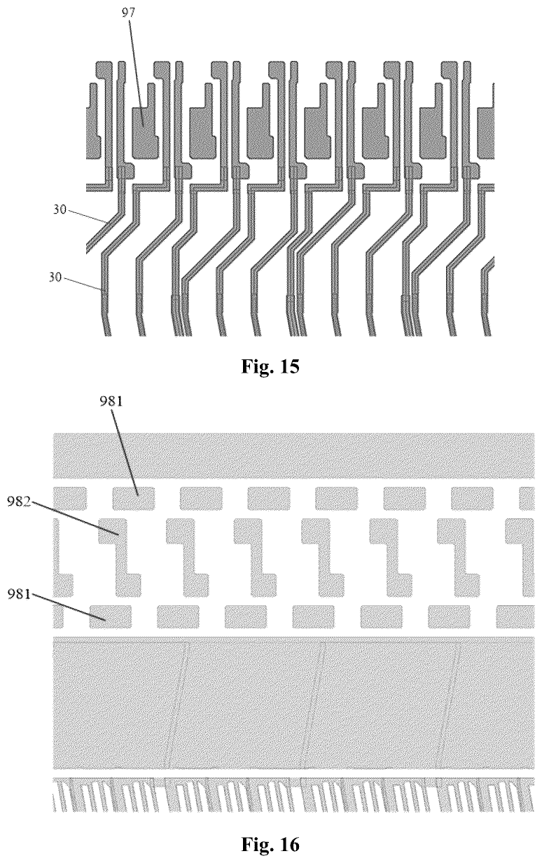

With reference to FIGS. 13-16, FIG. 13 is a schematic view showing a case where the plurality of electrostatic discharge sub-circuits is coupled to the data lines according to the embodiments of the present disclosure, FIG. 14 is a schematic view showing the layout of a gate metal layer, an active layer and a source/drain metal layer in FIG. 13, FIG. 15 is a schematic view showing the layout of the source/drain metal layer in FIG. 13, and FIG. 16 is a schematic view showing the layout of an indium tin oxide layer in FIG. 13.

The input electrode 93 of the first transistor T1, the output electrode 94 of the first transistor T1, the input electrode 95 of the second transistor T2, the output electrode 96 of the second transistor T2 are illustrated in FIG. 14.

As shown in FIGS. 14 and 15, the output electrode 94 of the first transistor T1 is coupled to the output electrode 96 of the second transistor T2 through a first conductive connection member 97.

As shown in FIGS. 7 and 13-16, the first conductive connection member 97 is coupled to a second conductive connection member 982 through a via hole, and the second conductive connection member 982 is coupled to the gate electrode of the second transistor T2 through a via hole. Third conductive connection members 981 are respectively coupled to the gate electrode of the first transistor T1 and the data line 30 through via holes.

Illustratively, in a same electrostatic discharge sub-circuit 601, the first transistor T1 and the second transistor T2 are arranged in an extending direction of the data line 30, and the input electrode of the first transistor T1 and the input electrode of the second transistor T2 are located on a same side of the data line 30. The output electrode of the first transistor T1 and the output electrode of the second transistor T2 are formed as one piece. The output electrode of the first transistor T1 and the output electrode of the second transistor T2 are coupled to the gate electrode of the second transistor T2 through a conductive connection pattern. The conductive connection pattern is made of indium tin oxide, and may be formed in a same patterning process as an electrode layer made of indium tin oxide in the display substrate. An orthogonal projection of the conductive connection pattern onto the base substrate 82 overlaps an orthogonal projection of the gate electrode of the second transistor T2 onto the base substrate 82 at an overlapping region, and the conductive connection pattern is coupled to the gate electrode of the second transistor T2 through a via hole. The orthogonal projection of the conductive connection pattern onto the base substrate 82 overlaps an orthogonal projection of the output electrode of the first transistor T1 onto the base substrate 82 at an overlapping region, and the conductive connection pattern is coupled to the output electrode of the first transistor T1 through a via hole.

On the basis of the above scheme, it is able for the input electrode of the first transistor T1, the input electrode of the second transistor T2 and the corresponding data line 30 to be formed in the same time in the same patterning process, so that the input electrode of the first transistor T1 and the input electrode of the second transistor T2 are directly connected to the corresponding data line 30 instead of a via hole bridging, thereby not only to reduce the difficulty in coupling between the electrostatic discharge circuit and the data line 30, but also to reduce the distance between the electrostatic discharge circuit and the data line 30. As a result, it is able to reduce the layout space occupied by the electrostatic discharge circuit and the data line 30 coupled thereto as a whole, thereby to provide the display substrate at the side where the profiled region 11 is located with a narrow frame.

As shown in FIG. 3, FIG. 4, and FIGS. 6 to 8, in some embodiments of the present disclosure, the plurality of electrostatic discharge sub-circuits 601 is divided into a plurality of electrostatic discharge sub-circuit groups 60 sequentially arranged in the profiled region 11, at least one of the electrostatic discharge sub-circuit groups 60 includes at least two electrostatic discharge sub-circuits 601, and gate electrodes of the second transistors T2 in at least one of the electrostatic discharge sub-circuit groups 60 are formed as one piece.

FIG. 4 shows seven complete electrostatic discharge sub-circuit groups 60, as well as one incomplete electrostatic discharge sub-circuit group 60 in the upper left corner of FIG. 4.

Illustratively, at least two electrostatic discharge sub-circuits 601 in at least one of the electrostatic discharge sub-circuit groups 60 are arranged in the first direction.

Illustratively, the quantity of electrostatic discharge sub-circuits 601 in at least one of the electrostatic discharge sub-circuit groups 60 may be the same or different.

Illustratively, in at least one of the electrostatic discharge sub-circuit groups 60, the output electrodes of a part of adjacent second transistors T2 are formed as one piece.

Illustratively, two adjacent electrostatic discharge sub-circuit groups 60 are arranged in a staggered manner along the extending direction of the data line 30.

In the display substrate of the above-mentioned embodiments, when the plurality of electrostatic discharge sub-circuits 601 is divided into the plurality of electrostatic discharge sub-circuit groups 60, it is able not only to effectively reduce the layout space occupied by the electrostatic discharge circuit, but also to reduce difficulty in the layout of the electrostatic discharge sub-circuits 601 in the profiled region 11, thereby to enable the layout of the electrostatic discharge circuit to match the shape of the profiled region 11 in a better manner.

When the gate electrodes of the second transistors T2 in at least one of the electrostatic discharge sub-circuit groups 60 are formed as one piece, it is able for the second transistors T2 in at least one of the electrostatic discharge sub-circuit groups 60 to be electrically connected to the common signal line in a better manner.

As shown in FIG. 4, in some embodiments of the present disclosure, the plurality of compensation scanning lines 20 is divided into a plurality of compensation scanning line groups 2, at least one of the compensation scanning line groups 2 includes at least two adjacent compensation scanning lines 20, and at least part of the electrostatic discharge sub-circuit groups 60 are located between adjacent compensation scanning line groups 2.

Illustratively, the profiled region 11 includes the bottom region 110, a first sloped region and a second sloped region, and the bottom region 110 is located between the first sloped region and the second sloped region. In the first sloped region, the electrostatic discharge sub-circuit groups 60 and the compensation scanning line groups 2 are alternately arranged. In the second sloped region, the electrostatic discharge sub-circuit groups 60 and the compensation scanning line groups 2 are alternately arranged.

On the basis of the above scheme, the compensation scanning lines 20 and the electrostatic discharge circuits are arranged more rationally, so as to make full use of the layout space of the profiled region 11, thereby to provide the display substrate at the side where the profiled region 11 is located with a narrow frame.

The present disclosure further provides in some embodiments a display panel including the display substrate in the above embodiments. The display panel further includes an opposing substrate arranged opposite to the display substrate.

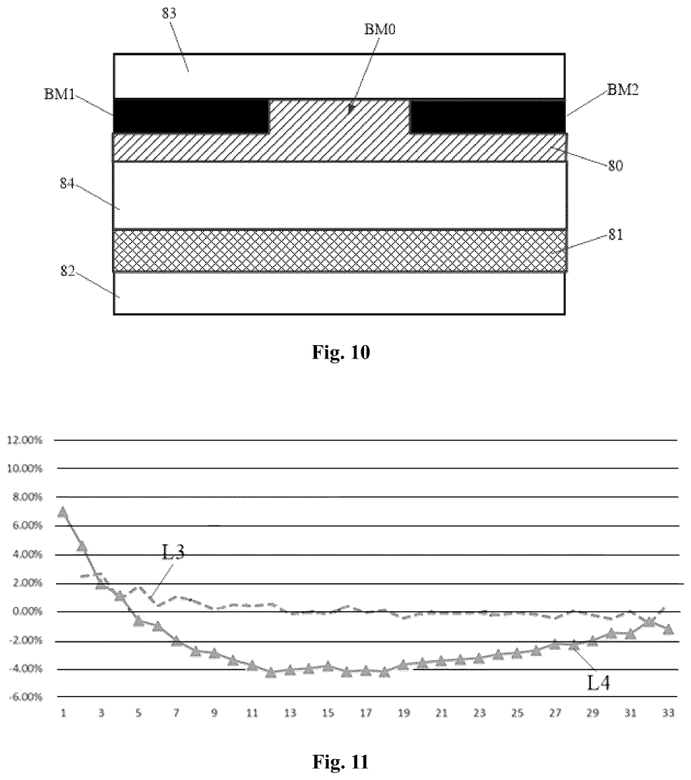

The opposing substrate includes, as shown in FIGS. 9 and 10, a black matrix layer BM, the black matrix layer BM includes a display region pattern BM1 and a non-display region pattern BM2, an orthogonal projection of the display region pattern BM1 onto the display substrate is located in the display region 10 of the display substrate, and an orthogonal projection of the non-display region pattern BM2 onto the display substrate is located in the peripheral region of the display substrate. A black matrix hollowed-out region BM0 is provided between the display region pattern BM1 and the non-display region pattern BM2.

Illustratively, the opposing substrate includes a color filter substrate. The opposing substrate includes a base substrate 83.

Illustratively, the display panel further includes a liquid crystal layer 84 between the display substrate and the opposing substrate.

Illustratively, the display panel includes an organic light emitting diode display panel.

Illustratively, the display region pattern BM1 and the non-display region pattern BM2 are independent from each other.

Through the black matrix hollowed-out region BM0 between the display region pattern BM1 and the non-display region pattern BM2, it is able to effectively avoid the electrostatic damage, thereby to adequately ensure the yield of the display panel.

In the display substrate, both the electrostatic discharge circuit and the loading compensation structure are arranged in the profiled region 11, and the electrostatic discharge circuit is arranged between the display region 10 and the loading compensation structure. The electrostatic discharge circuit is arranged close to the display region, and there is no other structure between the electrostatic discharge circuit and the display region 10, it is able for the electrostatic discharge circuit to be immediately adjacent to the data line 30 coupled thereto, thereby not only to reduce the difficulty in coupling between the electrostatic discharge circuit and the data line 30, but also to reduce the distance between the electrostatic discharge circuit and the data line 30. As a result, it is able to reduce the layout space occupied by the electrostatic discharge circuit and the data line 30 coupled thereto as a whole, thereby to provide the display substrate at the side where the profiled region 11 is located with a narrow frame. Furthermore, the electrostatic discharge circuit arranged at the lower frame of the display substrate in the related art is moved to the profiled region 11, thereby to effectively reduce the width of the lower frame of the display substrate. Moreover, when the electrostatic discharge circuit is moved to the profiled region 11, a part of the structure in the profiled region 11 may be removed, and a space originally used for arranging the part of the structure is used for arranging the electrostatic discharge circuit, so that even the electrostatic discharge circuit is moved to the profiled region 11, the width of the frame of the display substrate where the profiled region 11 is located is not increased. In addition, the loading compensation structure compensates for the loading compensation of the compensation scanning line 20, it is able to reduce the loading difference between the compensation scanning line 20 and the non-compensation scanning line, thereby to ensure the loading uniformity of the compensation scanning line 20 and the non-compensation scanning line in a better manner, and effectively improve the display quality of the display substrate.

Hence, when the display device includes the above-mentioned display substrate, it also has the above-mentioned beneficial effects, which will not be particularly defined herein.

As shown in FIGS. 3, 9 and 10, in some embodiments of the present disclosure, an orthogonal projection of the electrostatic discharge circuit of the display substrate onto the base substrate 82 of the display substrate is between an orthogonal projection of the loading compensation structure in the display substrate onto the base substrate 82 and an orthogonal projection of the black matrix hollowed-out region BM0 onto the base substrate 82. When the black matrix hollowed-out region BM0 is provided, it is able to prevent the static charge from entering BM1 through BM2, thereby to ensure the display.

As shown in FIG. 9, the black matrix hollowed-out region BM0 has a polygonal line shape, and the shape of the black matrix hollowed-out region BM0 matches the shape of the boundary of the display region.

On the basis of the above scheme, the loading compensation structure and the electrostatic discharge circuit are arranged more rationally, so as to make full use of the layout space of the profiled region 11, thereby to provide the display substrate at the side where the profiled region 11 is located with a narrow frame.

In some embodiments of the present disclosure, the opposing substrate further includes a support layer, and at least part of the support layer is located in the black matrix hollowed-out region BM0.

Illustratively, the support layer fills up the black matrix hollowed-out region BM0, so as to compensate for the level difference of the black matrix hollowed-out region BM0.

Illustratively, the support layer is in contact with the display region pattern BM1 and the non-display region pattern BM2 on both sides of the black matrix hollowed-out region BM0.

On the basis of the above scheme, it is able to support the opposing substrate in a better manner, thereby facilitating the yield of the display panel.

As shown in FIG. 10, in some embodiments of the present disclosure, the support layer includes a blue color filter pattern 80 including a portion in the black matrix hollowed-out region BM0 and a portion at a periphery of the black matrix hollowed-out region BM0.

Since the human eye is insensitive to blue, when the support layer includes the blue color filter pattern 80, it is able not only to ensure the supporting function, but also to ensure that even light leakage occurs in the black matrix hollowed-out region BM0, the light leakage phenomenon is not obvious, namely, mitigate the light leakage while ensuring the overall display uniformity.

In some embodiments of the present disclosure, the display panel further includes a sealant between the display substrate and the opposing substrate, an orthogonal projection of the sealant onto the display substrate is located in the peripheral region of the display substrate, and the orthogonal projection of the sealant onto the base substrate 82 at least partially overlaps an orthogonal projection of a hollowed-out region in the common signal line of the display substrate onto the base substrate 82.

Illustratively, when the display substrate and the opposing substrate are oppositely arranged to form a cell of the display panel, the sealant is formed between the display substrate and the opposing substrate, and cured by irradiating with the ultraviolet light, so that the frame of the display panel is fastened into the frame of the opposing substrate by using the sealant.

Illustratively, the orthogonal projection of the sealant onto the base substrate 82 at least partially overlaps the orthogonal projection of the compensation part 401 onto the base substrate 82.

Illustratively, the orthogonal projection of the sealant onto the base substrate 82 completely covers the common signal line.

The orthogonal projection of the sealant onto the base substrate 82 at least partially overlaps the orthogonal projection of the hollowed-out region in the common signal line in the display substrate onto the base substrate 82, so that when curing the sealant, it is able for the ultraviolet light to pass through the compensation part 401 and irradiate the sealant in a better manner, thereby improving the curing effect of the sealant in a better manner.

The present disclosure further provides in some embodiments a display device including the display panel in the above embodiments.

In the display panel, the black matrix hollowed-out region BM0 is provided between the display region pattern BM1 and the non-display region pattern BM2, so it is able to effectively avoid the electrostatic damage thereby to adequately guarantee the yield of the display panel. Both the electrostatic discharge circuit and the loading compensation structure are disposed in the profiled region 11, and the electrostatic discharge circuit is disposed between the display region 10 and the loading compensation structure. The electrostatic discharge circuit is arranged close to the display region, and there is no other structure between the electrostatic discharge circuit and the display region 10, it is able for the electrostatic discharge circuit to be immediately adjacent to the data line 30 coupled thereto, thereby not only to reduce the difficulty in coupling between the electrostatic discharge circuit and the data line 30, but also to reduce the distance between the electrostatic discharge circuit and the data line 30. As a result, it is able to reduce the layout space occupied by the electrostatic discharge circuit and the data line 30 coupled thereto as a whole, thereby to provide the display substrate at the side where the profiled region 11 is located with a narrow frame. Furthermore, the electrostatic discharge circuit arranged at the lower frame of the display substrate in the related art is moved to the profiled region 11, thereby to effectively reduce the width of the lower frame of the display substrate. Moreover, when the electrostatic discharge circuit is moved to the profiled region 11, a part of the structure in the profiled region 11 may be removed, and a space originally used for arranging the part of the structure is used for arranging the electrostatic discharge circuit, so that even the electrostatic discharge circuit is moved to the profiled region 11, the width of the frame of the display substrate where the profiled region 11 is located is not increased. In addition, the loading compensation structure compensates for the loading compensation of the compensation scanning line 20, it is able to reduce the loading difference between the compensation scanning line 20 and the non-compensation scanning line, thereby to ensure the loading uniformity of the compensation scanning line 20 and the non-compensation scanning line in a better manner, and effectively improve the display quality of the display substrate.

Hence, when the display device includes the above-mentioned display panel, it also has the above-mentioned beneficial effects, which will not be particularly defined herein.

It should be appreciated that, the display device may be any product or member having a display function, e.g., television, display, digital photo frame, mobile phone or tablet computer. The display device further includes a flexible circuit board, a printed circuit board and a back panel.

It should be appreciated that, the expression “at a same layer” refers to that the film layers are arranged on a same structural layer. Alternatively, for example, the film layers on a same layer may be layer structures formed through forming thin layers for forming specific patterns through a single film-forming process and then patterning the film layers with a same mask through a single patterning process. Depending on different specific patterns, a single patterning process may include multiple exposure, development or etching processes, and the specific patterns in the layer structures may be continuous or discontinuous. These specific patterns may also be arranged at different levels or have different thicknesses.

In the embodiments of the present disclosure, the order of the steps is not limited to the serial numbers thereof. For a person skilled in the art, any change in the order of the steps shall also fall within the scope of the present disclosure if without any creative effort.

It should be further appreciated that, the above embodiments have been described in a progressive manner, and the same or similar contents in the embodiments have not been repeated, i.e., each embodiment has merely focused on the difference from the others. Especially, the product embodiments are substantially similar to the method embodiments, and thus have been described in a simple manner, and the relevant part may refer to the description of the product embodiment.

Unless otherwise defined, any technical or scientific term used herein shall have the common meaning understood by a person of ordinary skills. Such words as “first” and “second” used in the specification and claims are merely used to differentiate different components rather than to represent any order, number or importance. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The aforementioned are merely specific implementations of the present disclosure, but the scope of the disclosure is by no means limited thereto. Any modifications or replacements that would easily occurred to those skilled in the art, without departing from the technical scope disclosed in the disclosure, should be encompassed in the scope of the present disclosure. Therefore, the scope of the present disclosure is to be determined by the scope of the claims.

1. A display substrate, comprising: a display region and a peripheral region surrounding the display region, the peripheral region comprising a bonding region and a profiled region, at least part of the display region being located between the bonding region and the profiled region;
wherein the display substrate further comprises a plurality of compensation scanning lines and a plurality of data lines, at least one of the compensation scanning lines comprises a portion located in the profiled region, and at least one of the data lines comprises a portion located in the display region and a portion located in the profiled region;
an electrostatic discharge circuit and a loading compensation structure are arranged in the profiled region, at least part of the electrostatic discharge circuit is located between the display region and the loading compensation structure;
the electrostatic discharge circuit is coupled to the plurality of data lines.

2. The display substrate according to claim 1, wherein the display substrate further comprises a common signal line, an orthogonal projection of the common signal line onto a base substrate of the display substrate at least partially overlaps an orthogonal projection of the plurality of compensation scanning lines onto the base substrate, and the common signal line serves as the loading compensation structure.

3. The display substrate according to claim 2, wherein the common signal line is arranged surrounding the display region, the common signal line comprises a compensation part and a non-compensation part, the compensation part is located in the profiled region, in a direction perpendicular to an extending direction of the compensation part, a minimum distance from a boundary of the compensation part close to the display region to a boundary of the compensation part away from the display region is greater than a width of the non-compensation part in a direction perpendicular to an extending direction of the non-compensation portion;
an orthogonal projection of the compensation part onto the base substrate of the display substrate at least partially overlaps the orthogonal projection of the plurality of compensation scanning lines onto the base substrate, and the compensation part serves as the loading compensation structure.

4. The display substrate according to claim 3, wherein the compensation part is formed in a grid structure.

5. The display substrate according to claim 3, wherein the compensation part comprises a first sub-part and a second sub-part, the first sub-part is located between the display region and the second sub-part; the first sub-part comprises a hollowed-out region;
the profiled region comprises a bottom region and a sloped region, along a direction from the sloped region to the bottom region, distances from a boundary of the first sub-part close to the display region to a boundary of the first sub-part away from the display region in a direction perpendicular to an extending direction of the first sub-part gradually decrease, and widths of the second sub-part in a direction perpendicular to an extending direction of the second sub-part gradually increase.

6. The display substrate according to claim 3, wherein the display substrate comprises sub-pixels in rows, and the sub-pixels in at least part of the rows comprise a plurality of sub-pixels arranged sequentially in a first direction; the compensation scanning line is coupled to each sub-pixel in a corresponding row;
the plurality of compensation scanning lines comprises a first compensation scanning line to an Nth compensation scanning line, the quantity of sub-pixels in a row corresponding to an Xth compensation scanning line is less than the quantity of sub-pixels in a row corresponding to an (X+1)th compensation scanning line, wherein 1≤X≤N−1;
an overlapping area between an orthogonal projection of the Xth compensation scanning line onto the base substrate and the orthogonal projection of the compensation part onto the base substrate is greater than an overlapping area between an orthogonal projection of the (X+1)th compensation scanning line onto the base substrate and the orthogonal projection of the compensation part onto the base substrate.

7. The display substrate according to claim 6, wherein the display region comprises a first display region and two second display regions, the first display region is located on a same side of the two second display regions, and the profiled region is located between the two display regions;
the sub-pixels in rows comprise first sub-pixels in rows and second sub-pixels in rows, wherein the first sub-pixels in rows are located in the first display region, and among the second sub-pixels in rows, one part of the second sub-pixels in each row is located in one of the second display regions, and the other part of the second sub-pixels in each row is located in the other one of the second display regions;
at least one of the plurality of compensation scanning lines corresponds to the second sub-pixels in one row, at least one of the compensation scanning lines comprises a first line segment, a second line segment and a third line segment sequentially coupled, the first line segment and the third line segment each comprise at least a portion extending in the first direction, and the second line segment extends along a boundary of the profiled region;
an orthogonal projection of the first line segment onto the base substrate at least partially overlaps the orthogonal projection of the compensation part onto the base substrate, an orthogonal projection of the second line segment onto the base substrate at least partially overlaps the orthogonal projection of the compensation part onto the base substrate, and an orthogonal projection of the third line segment onto the base substrate at least partially overlaps the orthogonal projection of the compensation part onto the base substrate.

8. The display substrate according to claim 7, wherein the display substrate further comprises a plurality of non-compensation scanning lines, at least part of the non-compensation scanning lines are located in the first display region, at least one of the plurality of non-compensation scanning lines corresponds to, and is coupled to, the first sub-pixels in one row;
the compensation scanning lines and the non-compensation scanning lines are arranged at a same layer, and the common signal line and the data lines are arranged at a same layer.

9. The display substrate according to claim 3, wherein the non-compensation part comprises a first non-compensation part and a second non-compensation part, the display region is located between the first non-compensation part and the second non-compensation part, a first end of the first non-compensation part is coupled to a first end of the compensation part, a second end of the first non-compensation part is located in the bonding region, a first end of the second non-compensation part is coupled to a second end of the compensation part, and a second end of the second non-compensation part is located in the bonding region.

10. The display substrate according to claim 9, wherein the display substrate further comprises a shielding line in the peripheral region, the shielding line is arranged surrounding the display region, and the common signal line is located between the display region and the shielding line.

11. The display substrate according to claim 2, wherein the electrostatic discharge circuit comprises a plurality of electrostatic discharge sub-circuits corresponding to the plurality of data lines respectively;
at least one of the electrostatic discharge sub-circuits comprises a first transistor and a second transistor, a gate electrode of the first transistor is coupled to an input electrode of the first transistor, the input electrode of the first transistor is coupled to an input electrode of the second transistor, an output electrode of the first transistor is coupled to an output electrode of the second transistor, and a gate electrode of the second transistor is coupled to the output electrode of the second transistor; the input electrode of the first transistor is coupled to a corresponding data line.

12. The display substrate according to claim 11, wherein the input electrode of the first transistor and the input electrode of the second transistor are formed as an integral structure with a corresponding data line.

13. The display substrate according to claim 11, wherein the plurality of electrostatic discharge sub-circuits is divided into a plurality of electrostatic discharge sub-circuit groups arranged sequentially in the profiled region, at least one of the electrostatic discharge sub-circuit groups comprises at least two electrostatic discharge sub-circuits, and gate electrodes of second transistors in at least one of the electrostatic discharge sub-circuit groups are formed as one piece.

14. The display substrate according to claim 13, wherein the plurality of compensation scanning lines is divided into a plurality of compensation scanning line groups, at least one of the compensation scanning line groups comprises at least two adjacent compensation scanning lines, and at least part of the electrostatic discharge sub-circuit groups are located between adjacent compensation scanning line groups.

15. A display panel, comprising the display substrate according to claim 1, wherein the display panel further comprises an opposing substrate arranged opposite to the display substrate; the opposing substrate comprises:
a black matrix layer, wherein the black matrix layer comprises a display region pattern and a non-display region pattern, an orthogonal projection of the display region pattern onto the display substrate is located in the display region of the display substrate, and an orthogonal projection of the non-display region pattern onto the display substrate is located in the peripheral region of the display substrate; a black matrix hollowed-out region is provided between the display region pattern and the non-display region pattern.

16. The display panel according to claim 15, wherein an orthogonal projection of the electrostatic discharge circuit of the display substrate onto the base substrate of the display substrate is located between an orthogonal projection of the loading compensation structure of the display substrate onto the base substrate and an orthogonal projection of the black matrix hollowed-out region onto the base substrate.

17. The display panel according to claim 15, wherein the opposing substrate further comprises a support layer, and at least part of the support layer is located in the black matrix hollowed-out region.

18. The display panel according to claim 17, wherein the support layer comprises a blue color filter pattern comprising a portion in the black matrix hollowed-out region and a portion at a periphery of the black matrix hollowed-out region.

19. The display panel according to claim 17, wherein the display panel further comprises a sealant between the display substrate and the opposing substrate, an orthogonal projection of the sealant onto the display substrate is located in the peripheral region of the display substrate, and the orthogonal projection of the sealant onto the base substrate at least partially overlaps an orthogonal projection of a hollowed-out region in the common signal line of the display substrate onto the base substrate.

20. A display device comprising the display panel according to claim 15.
